(19) United States
(12) Patent Application Publication
(10) Pub. No.: US 2020/0208254 A1
(43) Pub. Date: Jul. 2, 2020

(54) METHOD OF INCREASING CORROSION RESISTANCE OF MAGNESIUM MEMBER, AND MAGNESIUM MEMBER HAVING EXCELLENT CORROSION RESISTANCE

(71) Applicant: KOREA INSTITUTE OF SCIENCE AND TECHNOLOGY, Seoul (KR)

(72) Inventors: Yu Chan KIM, Seoul (KR); Hyun Kwang SEOK, Seoul (KR); SEUNG HEE HAN, Seoul (KR); Hojeong JEON, Seoul (KR); Myoung-Ryul OK, Seoul (KR); Hyunseon SEO, Seoul (KR); Kyoung Won PARK, Seoul (KR); Yeon Wook JUNG, Seoul (KR); Pil Ryung CHA, Seoul (KR)

(21) Appl. No.: 16/691,613

(22) Filed: Nov. 22, 2019

(30) Foreign Application Priority Data
Dec. 26, 2018 (KR) 10-2018-0169061

(51) Int. Cl. C23C 14/16; C23C 14/48; C23C 14/35; C23C 14/34; C23C 14/32

(52) U.S. Cl. CPC C23C 14/16; C23C 14/48; C23C 14/325; C23C 14/3485; C23C 14/35

(57) ABSTRACT

Provided is a method of increasing corrosion resistance of a magnesium (Mg) member. The method includes preparing a Mg member, and ion-implanting a doping element into a surface of the Mg member. Herein, the doping element includes an element capable of increasing a Fermi energy level of magnesium oxide (MgO) when doped on MgO.

### CROSS-REFERENCE TO RELATED PATENT APPLICATION

This application claims the benefit of Korean Patent Application No. 10-2018-0169061, filed on Dec. 26, 2018, in the Korean Intellectual Property Office, the disclosure of which is incorporated herein in its entirety by reference.

### BACKGROUND

### 1. Field

The present invention relates to a method of increasing corrosion resistance of a magnesium (Mg) member, and a Mg member synthesized using the method to achieve excellent corrosion resistance.

### 2. Description of the Related Art

Due to excellent specific strength, dimensional stability, machinability, and vibration damping capacity characteristics, magnesium (Mg) or a Mg alloy, which is a lightweight metal, is currently applicable to various fields requiring light weights and biodegradability, e.g., vehicles such as cars, trains, airplanes, and ships, home appliances, medical devices, and household items, and thus is regarded as a significant material of industries. However, Mg has high chemical activity and low corrosion resistance.

In general, to minimize bad influence of impurities such as iron (Fe), nickel (Ni), and copper (Cu) on corrosion resistance of a Mg alloy, the content of the impurities is reduced through multiple refining processes. However, considering process costs, control of the impurity content based on refinement has a limitation and thus may not easily increase corrosion resistance to above a certain level.

It is reported that, when titanium (Ti) is added to a magnesium-aluminum (Al) alloy, e.g., AZ31, corrosion resistance is increased because an Al-rich α phase occurring due to reaction between Ti and Al suppresses growth of grains and thus the grains have a small size. However, the grain size reduction method using the Al-rich α phase may not achieve the corrosion resistance increasing effect for a plate member rolled at high temperature, because the Al-rich α phase, which is present in a network structure at grain boundaries before being rolled, is completely decomposed in the high-temperature rolling process and thus the effect of suppressing growth of grains is no longer achievable. That is, in a method of synthesizing an intermetallic compound based on reaction between Ti and an alloy element in a Mg alloy, when heat treatment or processing is performed at a temperature equal to or higher than a decomposition temperature of the intermetallic compound, a grain size reduction effect is lost and thus corrosion resistance may not be increased. Furthermore, when pure Mg not containing an alloy element is used, an intermetallic compound is not synthesized and thus the above-method is not applicable.

### SUMMARY

The present invention provides a method of increasing corrosion resistance of a magnesium (Mg) member, the method being applicable to both a Mg alloy and pure Mg, and a Mg member synthesized using the method to achieve excellent corrosion resistance. However, the scope of the present invention is not limited thereto.

According to an aspect of the present invention, there is provided a method of increasing corrosion resistance of a magnesium (Mg) member.

The method includes preparing a Mg member, and ion-implanting a doping element into a surface of the Mg member. Herein, the doping element includes an element capable of increasing a Fermi energy level of magnesium oxide (MgO) when doped on MgO.

The ion-implanting may include generating a high-concentration region having a higher concentration of the doping element compared to the surface of the Mg member, in a region under the surface.

The doping element may include one selected from among titanium (Ti), gadolinium (Gd), hafnium (Hf), yttrium (Y), tellurium (Te), cerium (Ce), and phosphorus (P).

The ion-implanting may be performed using an ion beam ion-implantation process or a plasma ion-implantation process.

The plasma ion-implantation process may include an arc plasma ion-implantation process or a high-power impulse magnetron sputtering (HiPIMS) ion-implantation process.

According to another aspect of the present invention, there is provided magnesium (Mg) member having excellent corrosion resistance.

The Mg member includes a high-concentration region having a higher concentration of a heterogeneous element compared to a surface of the Mg member, in a region under the surface. Herein, the heterogeneous element includes an element capable of increasing a Fermi energy level of magnesium oxide (MgO) when doped on MgO.

The heterogeneous element may include one selected from among titanium (Ti), gadolinium (Gd), hafnium (Hf), yttrium (Y), tellurium (Te), cerium (Ce), and phosphorus (P).

At least a partial region between the surface and the region under the surface may have an amorphous phase.

The Mg member may include pure Mg or a Mg alloy.

### BRIEF DESCRIPTION OF THE DRAWINGS

The above and other features and advantages of the present invention will become more apparent by describing in detail embodiments thereof with reference to the attached drawings in which:

FIGS. 1A and 1B are graphs conceptually showing diffusion behaviors of interstitial defects and vacancies in a magnesium oxide (MgO) layer which is a corrosion layer produced on a surface of magnesium (Mg) when Mg is corroded;

FIG. 2 is a graph showing a density of states of MgO, which is calculated based on first principles calculation;

FIGS. 3A and 3B are graphs showing results of calculating formation energies of defects according to a Fermi energy level in a pure MgO layer by using a Heyd-Scuseria-Ernzerhof (HSE) exchange-correlation functional;

FIG. 4 is a graph showing a density of states of MgO doped with titanium (Ti);

FIGS. 5A and 5B are graphs showing results of calculating formation energies of defects according to a Fermi energy level in a Ti-doped MgO layer;

FIGS. 6A and 6B are graphs conceptually showing diffusion behaviors of ions and vacancies in a MgO layer which is a corrosion layer produced on a surface of Ti-doped Mg when Ti-doped Mg is corroded;

FIGS. 7A to 7F are graphs showing changes in an energy bandgap and a Fermi energy level of MgO in cases when gadolinium (Gd), hafnium (Hf), yttrium (Y), tellurium (Te), cerium (Ce), and phosphorus (P) are doped;

FIG. 8 is an image showing a result of analyzing a microstructure of a Mg sample according to an experimental example of the present invention, after a corrosion test;

FIGS. 9A to 9C and 10A to 10C are graphs showing results of analyzing components of Mg samples according to experimental examples of the present invention, based on X-ray photoelectron spectroscopy (XPS);

FIGS. 11 and 12 are graphs showing results of analyzing concentrations of Ti element according to depths based on XPS; and

FIG. 13 is a schematic view of a high-power impulse magnetron sputtering (HiPIMS) apparatus.

### DETAILED DESCRIPTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art.

In the following description, a magnesium (Mg) member may include both pure Mg and a Mg alloy.

When Mg is exposed to a corrosion environment, e.g., the atmosphere, or is in contact with a moisture environment, Mg reacts with oxygen (O₂) in the atmosphere or moisture (H₂O) in the moisture environment and thus corrosion occurs. A corrosion layer made of magnesium oxide (MgO) is produced on the surface of Mg as a result of corrosion, and grows to a larger thickness when corrosion is continued.

The present inventors have found that growth of MgO, which is a product of corrosion, may be suppressed by ion-implanting a certain element into the surface of Mg, and thus corrosion resistance of Mg may be greatly increased. The certain element refers to an element doped on pure MgO to increase a Fermi energy level of MgO toward a conduction band. The present inventors have studied for a cause of the increase in the corrosion resistance due to ion-implantation of the certain element, in terms of defect formation energy, and have found that growth of MgO may be suppressed by changing the Fermi energy level of MgO by doping the certain element thereon.

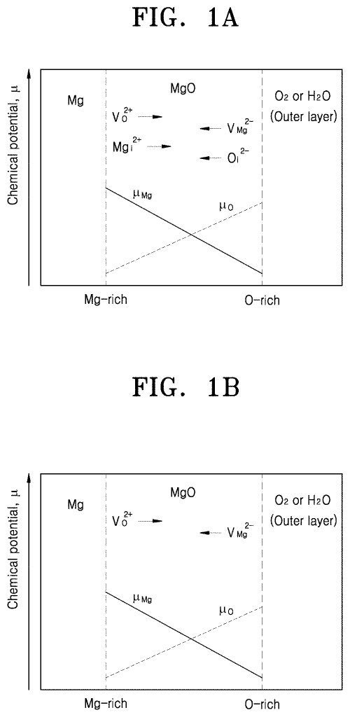

Growth of the corrosion layer made of MgO may be understood as diffusion of magnesium interstitial defects (Mgᵢ²⁺), oxygen interstitial defects (Oᵢ²⁻), and vacancies (V_{Mg}²⁻ and V_{O}²⁺) through the corrosion layer. Diffusion of ions in the corrosion layer and diffusion of vacancies corresponding to positions of atoms of the ions are driven by chemical potential gradients of magnesium (Mg) and oxygen (O) in the corrosion layer (see FIG. 1A).

FIGS. 1A and 1B are graphs conceptually showing diffusion behaviors of ions and vacancies in a MgO layer which is a corrosion layer produced on the surface of Mg when Mg is corroded.

Referring to FIG. 1A, a region close to Mg (e.g., Mg-rich and Mg) is a region where a chemical potential μ_{Mg} of Mg is high, and a region close to outside (e.g., O-rich and Outer layer) is a region where a chemical potential μ_{O} of O is high. V_{O}²⁺ and Mgᵢ²⁺ defects generated in the region close to Mg (e.g., Mg-rich) are diffused through the MgO layer, which is the corrosion layer, toward the outer region (e.g., O-rich) where the chemical potential μ_{Mg} of Mg is low. On the contrary, V_{Mg}²⁻ and Oᵢ²⁻ defects generated in the outer region are diffused toward Mg where the chemical potential μ_{O} of O is low.

Types of defects participating in corrosion layer production reaction in the MgO layer may be determined by comparing defect formation energies of the defects based on a function of a Fermi energy level of MgO. To this end, the Fermi energy level of the MgO layer and values of formation energies of the defects according to the Fermi energy level need to be provided.

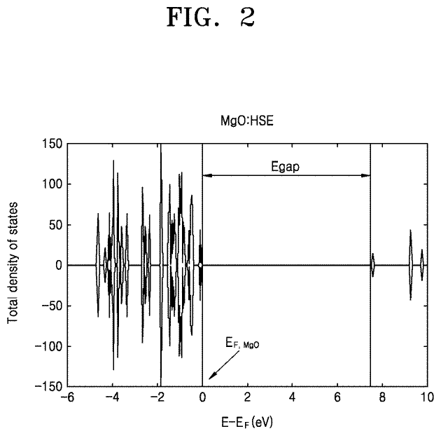

FIG. 2 is a graph showing a density of states of pure MgO, which is calculated from an electronic structure of a ground state by using a Heyd-Scuseria-Ernzerhof (HSE) exchange-correlation functional based on first principles calculation. FIG. 2 shows an energy bandgap E_{gap} and a Fermi energy level E_{F,MgO} of pure MgO (the Fermi energy level E_{F,MgO} is indicated as a point where E-E_{F} has a value 0 on an X axis).

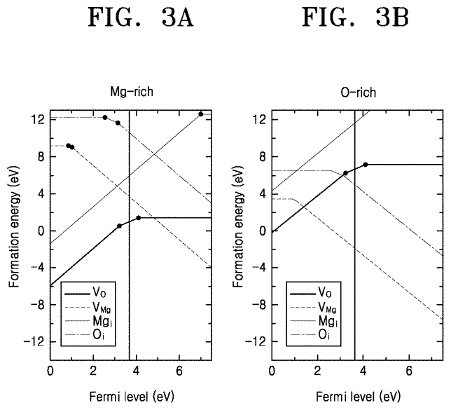

FIGS. 3A and 3B are graphs showing results of calculating formation energies of defects according to a Fermi energy level in a pure MgO layer by using a HSE exchange-correlation functional. FIG. 3A shows a result in a region close to Mg (e.g., Mg-rich), and FIG. 3B shows a result in a region close to outside (e.g., O-rich). In FIGS. 3A and 3B, the Fermi energy level of pure MgO, which is calculated in FIG. 2, is indicated as solid vertical lines.

Referring to FIGS. 3A and 3B, at the Fermi energy level of pure MgO, it is shown that the defect formation energy of V_{O}²⁺ has the largest negative value in the region close to Mg, and the defect formation energy of V_{Mg}²⁻ has the largest negative value in the region close to outside. This means that V_{O}²⁺ is the most stable in the region close to Mg, and V_{Mg}²⁻ is the most stable in the region close to outside. Therefore, it is concluded that defects participating in production of a MgO layer include V_{O}²⁺ of the region close to Mg, and V_{Mg}²⁻ of the region close to outside. V_{O}²⁺ and V_{Mg}²⁻ move away from each other due to chemical potential gradients of Mg and O, and thus contribute to growth of MgO, which means corrosion of Mg, as shown in FIG. 1B.

The present inventors have found that, when Mg is doped with a certain element, a Fermi energy level of a MgO layer corresponding to a corrosion layer is changed, and thus types of defects which are the most stable in a region close to Mg and a region close to outside may be changed. As such, the present inventors proposes a method of suppressing growth of MgO (i.e., a method of suppressing corrosion of Mg) by doping an element capable of increasing the Fermi energy level of MgO toward a conduction band. According to a study of the present inventors based on the defect chemical theory, examples of the element capable of achieving the above-described effect include titanium (Ti), gadolinium (Gd), hafnium (Hf), yttrium (Y), tellurium (Te), cerium (Ce), and phosphorus (P).

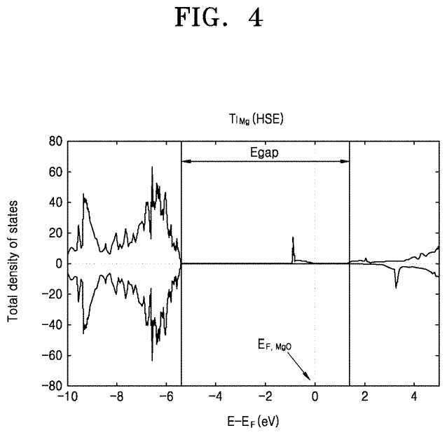

For example, FIG. 4 is a graph showing a change in a Fermi energy level E_{F,MgO} of MgO in an energy bandgap E_{gap} in a case when Ti is implanted as a doping element. Compared to FIG. 2, it is shown that a new energy level occurs in the energy bandgap E_{gap} due to doping of Ti, and thus the Fermi energy level E_{F,MgO} is increased and moved toward a conduction band.

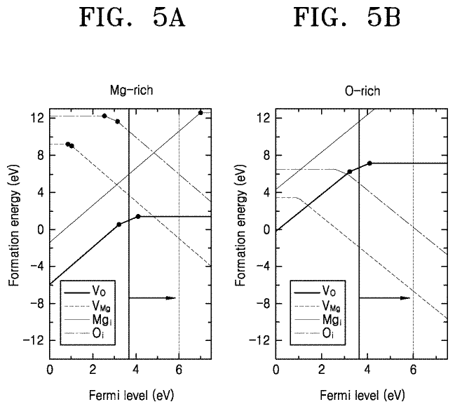

FIGS. 5A and 5B are graphs showing results of calculating formation energies of defects according to a Fermi energy level in a Ti-doped MgO layer. Referring to FIGS. 5A and 5B, the Fermi energy level is increased due to doping of Ti (see arrows), and types of defects which are the most stable in terms of energy in a Mg region and an outer region are changed at the changed Fermi energy level (see dashed vertical lines).

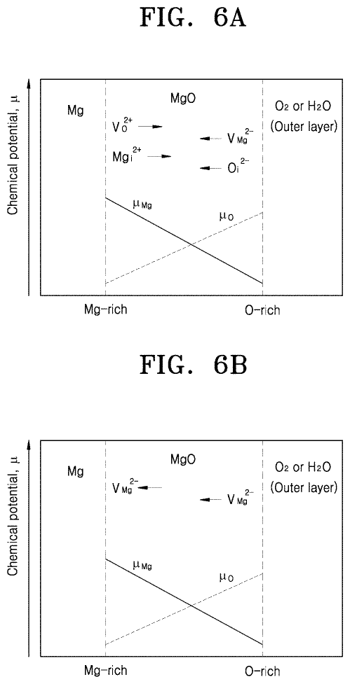

That is, referring to FIGS. 5A and 5B, at the Fermi energy level, it is shown that the defect formation energy of V_{Mg}²⁻ has the largest negative value in a region close to Mg, and the defect formation energy of V_{Mg}²⁻ has the largest negative value in a region close to outside. Therefore, it is concluded that defects participating in production of a MgO layer in terms of energy include V_{Mg}²⁻ of the region close to Mg, and V_{Mg}²⁻ of the region close to outside, as shown in FIG. 6B. FIG. 6B shows that V_{Mg}²⁻ having negative charges is generated at both sides of MgO and is accumulated on the region close to Mg due to a chemical potential gradient of Mg. V_{Mg}²⁻ vacancies accumulated on a Mg—MgO interface hinder Mg from dissolving into MgO at the interface. Consequently, growth of a MgO layer, which is a corrosion product, is suppressed.

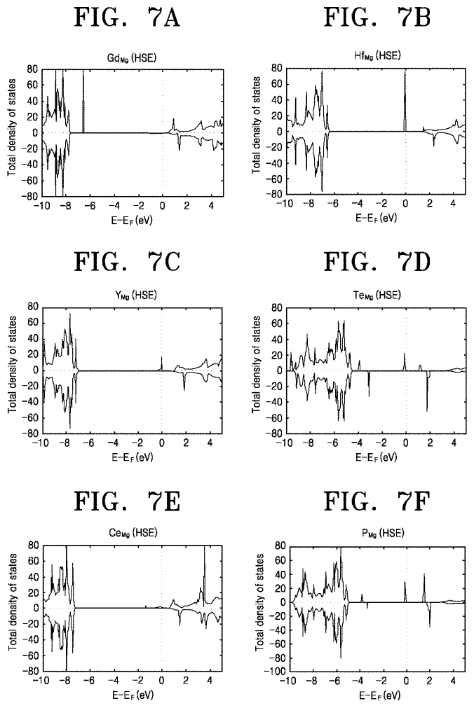

FIGS. 7A to 7F are graphs showing changes in an energy bandgap and a Fermi energy level of MgO in cases when Gd, Hf, Y, Te, Ce, and P are doped as elements capable of achieving the same effect as Ti. Referring to FIGS. 7A to 7F, in all cases, it is shown that a new energy level occurs in the energy bandgap of MgO, and thus the Fermi energy level is increased toward a conduction band. Like Ti, the above-mentioned elements may also serve to suppress corrosion of Mg.

Therefore, a method of increasing corrosion resistance of a Mg member, according to an embodiment of the present invention, includes ion-implanting a doping element into the surface of a prepared Mg member. The doping element is an element capable of increasing a Fermi energy level of MgO when doped on MgO, and may include one selected from among Ti, Gd, Hf, Y, Te, Ce, and P.

The ion-implantation process refers to a process of implanting a certain element into the surface of a sample by ionizing the element and then accelerating the ionized element with a high voltage.

As the ion-implantation process, an ion beam ion-implantation process commonly used in a semiconductor manufacturing process may be used. For example, to dope P, P ions are generated by ionizing a source gas, e.g., PH₃, in an ion generator, an ion beam is generated by focusing the P ions, and the P ions are implanted into a sample by accelerating the ion beam with a high voltage by a predetermined distance.

As another example of the ion-implantation process, a plasma ion-implantation process for mounting a sample in plasma generated in a chamber, and implanting ions in the plasma into the sample by accelerating the ions with a high negative voltage toward the sample.

The plasma ion-implantation process may be performed using, for example, an arc plasma ion-implantation process for generating arc plasma by applying a high pulse voltage between a metal target and a sample. Metal ions in the arc plasma are accelerated by a high negative voltage applied to the sample and are implanted into the sample.

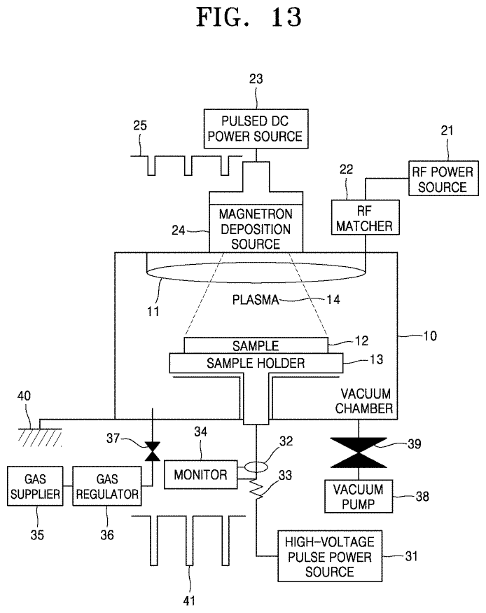

As another example, a high-power impulse magnetron sputtering (HiPIMS) process using a metal as a sputtering target may be used. FIG. 13 is a schematic view of a HiPIMS apparatus. Referring to FIG. 13, the HiPIMS apparatus includes a magnetron deposition source 24 for mounting a sputtering target in a vacuum chamber 10, and a sample holder 13 placed in the vacuum chamber 10 to face the magnetron deposition source 24 and to mount a sample 12 thereon. A pulsed direct-current (DC) power source 23 for supplying a pulsed DC current is connected to the magnetron deposition source 24, and a high-voltage pulse power source 31 for supplying a high-voltage pulse is connected to the sample holder 13. When a pulsed DC current is applied to the sputtering target that is the magnetron deposition source 24, plasma 14 is generated and sputtering of atoms occurs from the sputtering target. The sputtered atoms are ionized in the plasma 14, and then are accelerated and implanted with high energy into the sample 12 to which a high-voltage pulse is applied.

A Mg member ion-implanted with a doping element based on the above-described methods is characterized in that a region in which a concentration of a doping element is higher than that of a surface is generated in a region under the surface. Based on ion-implantation, when ions accelerated with high energy are implanted into the surface of the Mg member, the ions consume the energy while proceeding in the Mg member and colliding with Mg atoms, and stop proceeding at a depth where the energy is completely consumed. Therefore, when the doping element is put into the Mg member based on ion-implantation, the doping element has the highest concentration in the region under the surface of the Mg member.

Meanwhile, based on ion-implantation, since a doping element is implanted with high energy and collides with Mg atoms, the Mg atoms on a path of the doping element may be randomly placed out of a lattice and may have an amorphous phase.

Therefore, a Mg member synthesized according to an embodiment of the present invention may have a structure in which a high-concentration region having a high concentration of a doping element, which is a heterogeneous element, is generated in a region under a surface and at least a partial region between the surface and the high-concentration region has an amorphous phase.

Embodiments will now be described for better understanding of the present invention. However, experimental examples to be described below should be considered in a descriptive sense only and not for purposes of limitation.

### EMBODIMENTS

Samples were synthesized by ion-implanting Ti into pure Mg and a Mg alloy containing 3 wt % of zinc (Zn) (e.g., Mg-3Zn), by using the HiPIMS apparatus illustrated in FIG. 13. In this case, the ion-implanting process was performed for 20 minutes, 40 minutes, and 60 minutes. A base pressure in a chamber was controlled to 3×10⁻⁵ Torr, a working pressure was controlled to 2 mTorr, and a flow rate of an argon (Ar) gas was controlled to 10 sccm. The Mg member sample types and the ion-implantation times are shown in Table 1.

TABLE 1

| | Mg | Ion- | Ti |
|---|---|---|---|
| | member | implantation | implantation |
| Sample | type | time (min.) | depth (nm) |
| Experimental Example 1 | Mg-3Zn | 20 | 80 nm |
| Experimental Example 2 | Mg-3Zn | 40 | 120 nm |
| Experimental Example 3 | Mg-3Zn | 60 | 160 nm |
| Experimental Example 4 | Pure Mg | 20 | 80 nm |
| Experimental Example 5 | Pure Mg | 40 | 120 nm |
| Experimental Example 6 | Pure Mg | 60 | 160 nm |

Pulsed DC power was applied to a Ti target at a frequency of 200 Hz, a pulse voltage of −1 kV, and an average current of 300 mA. A high-voltage pulse was applied to the samples at a frequency of 200 Hz synchronized with the pulsed DC power, a pulse voltage of −30 kV, and an average current of 12 mA. In this case, the ion-implantation process was performed on only a single surface of each sample, and the other surface of the sample, on which the ion-implantation process was not performed, was used as a comparative example.

The ion-implanted samples were immersed and corroded in a Dulbecco's minimum essential medium (DMEM) solution for 2 days in an incubator, and cross-sectional microstructures of the samples were analyzed using scanning electron microscopy (SEM). To find out composition distributions of Ti atoms according to the ion-implantation times, compositions of the samples were analyzed using X-ray photoelectron spectroscopy (XPS).

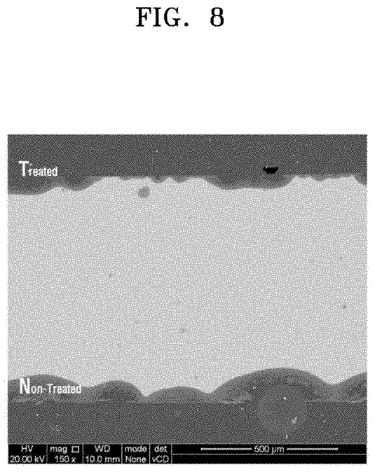

FIG. 8 is a SEM image showing a result of analyzing a microstructure of the Mg member sample according to Experimental Example 5 of the present invention, after a corrosion test. In FIG. 8, an upper part of the Mg member is a Ti ion-implanted part (Treated), and a lower part thereof is a non-ion-implanted part (Non-Treated).

Referring to FIG. 8, it is shown that corrosion is remarkably suppressed in the ion-implanted upper part compared to the non-ion-implanted lower part. That is, the non-ion-implanted lower part is seriously corroded over a whole area thereof, and has a large corrosion depth. On the contrary, the ion-implanted upper part is slightly corroded in some regions thereof and an overall corrosion depth thereof is less than that of the lower part. As such, it may be concluded that corrosion resistance of the Mg member is remarkably increased by ion-implanting Ti.

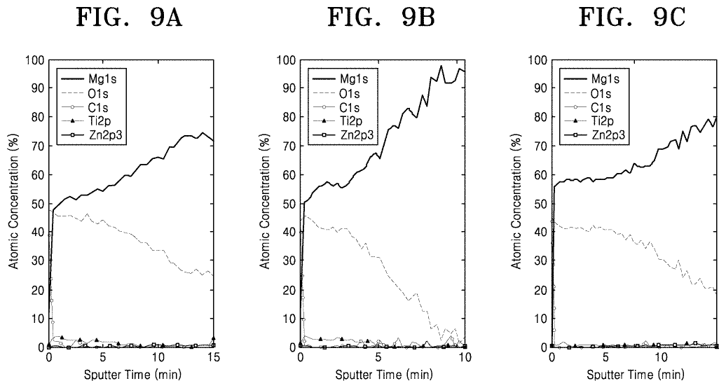

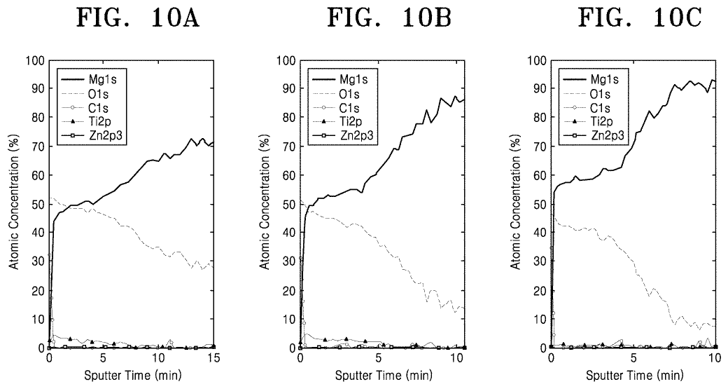

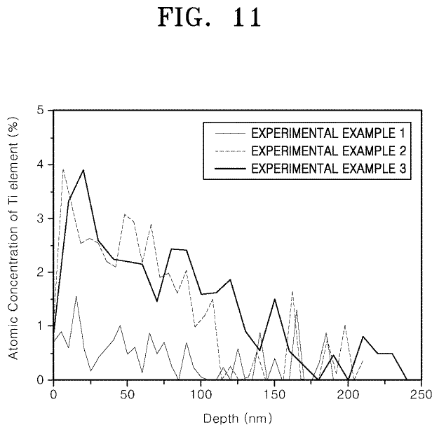

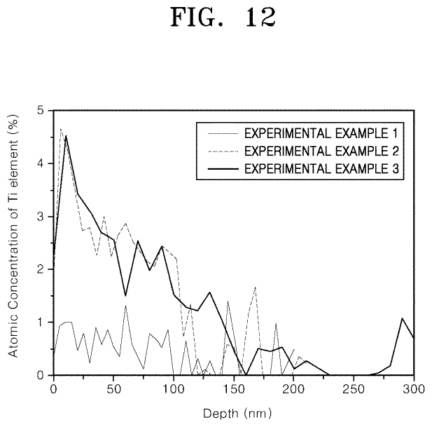

FIGS. 9A to 9C and 10A to 10C are depth profile graphs showing results of analyzing composition variations from surfaces of the Mg member samples according to the experimental examples of the present invention, to regions under the surfaces based on XPS. FIGS. 9A to 9C show analysis results of the samples of Experimental Examples 1 to 3, and FIGS. 10A to 10C show analysis results of the samples of Experimental Examples 4 to 6. FIGS. 11 and 12 are graphs showing Ti-related parts of the graphs of FIGS. 9A to 9C and 10A to 10C to more specifically show composition distributions of Ti according to implantation depths thereof.

Referring to FIGS. 9A to 12, it is shown that concentrations of Ti atoms are high in the regions under the surfaces of the Mg members regardless of the types of the Mg members. In ion-implantation, ions accelerated with high energy permeate into a surface and thus a region at a predetermined depth from the surface has the highest concentration of the implanted ions. As such, it may be concluded that Ti is normally ion-implanted into the Mg members.

Table 1 shows implantation depths of Ti according to Ti ion-implantation conditions. Referring to Table 1, it is shown that the implantation depth is increased from 80 nm to 120 nm and 160 nm when the ion-implantation time is increased from 20 minutes to 40 minutes and 60 minutes. Referring to FIGS. 11 and 12, it is shown that, as expected, a total amount of Ti implanted into the Mg member is increased when the Ti ion-implantation time is increased.

According to the afore-described embodiments of the present invention, corrosion resistance of Mg having high chemical activity and high corrosiveness may be remarkably increased by doping a certain element thereon by using ion-implantation. A Mg member synthesized according to an embodiment of the present invention to achieve excellent corrosion resistance may be useful in various fields requiring light weights and biodegradability, e.g., vehicles such as cars, trains, airplanes, and ships, home appliances, medical devices, and household items. However, the scope of the present invention is not limited thereto.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A method of increasing corrosion resistance of a magnesium (Mg) member, the method comprising:
preparing a Mg member; and
ion-implanting a doping element into a surface of the Mg member,
wherein the doping element comprises an element capable of increasing a Fermi energy level of magnesium oxide (MgO) when doped on MgO.

2. The method of claim 1, wherein the ion-implanting comprises generating a high-concentration region having a higher concentration of the doping element compared to the surface of the Mg member, in a region under the surface.

3. The method of claim 1, wherein the doping element comprises one selected from among titanium (Ti), gadolinium (Gd), hafnium (Hf), yttrium (Y), tellurium (Te), cerium (Ce), and phosphorus (P).

4. The method of claim 1, wherein the ion-implanting is performed using an ion beam ion-implantation process or a plasma ion-implantation process.

5. The method of claim 4, wherein the plasma ion-implantation process comprises an arc plasma ion-implantation process or a high-power impulse magnetron sputtering (HiPIMS) ion-implantation process.

6. A magnesium (Mg) member having excellent corrosion resistance, the Mg member comprising a high-concentration region having a higher concentration of a heterogeneous element compared to a surface of the Mg member, in a region under the surface,
wherein the heterogeneous element comprises an element capable of increasing a Fermi energy level of magnesium oxide (MgO) when doped on MgO.

7. The Mg member of claim 6, wherein the heterogeneous element comprises one selected from among titanium (Ti), gadolinium (Gd), hafnium (Hf), yttrium (Y), tellurium (Te), cerium (Ce), and phosphorus (P).

8. The Mg member of claim 6, wherein at least a partial region between the surface and the region under the surface has an amorphous phase.

9. The Mg member of claim 6, wherein the Mg member” comprises pure Mg or a Mg alloy.
